(19) United States
(12) Patent Application Publication
(10) Pub. No.: US 2024/0120333 A1
(43) Pub. Date: Apr. 11, 2024

(54) GROUP III-N BASED SEMICONDUCTOR THREE-DIMENSIONAL INTEGRATED CIRCUIT

(71) Applicant: NATIONAL YANG MING CHIAO TUNG UNIVERSITY, HSINCHU CITY (TW)

(72) Inventors: TIAN-LI WU, TAOYUAN CITY (TW); YEN-WEI LIU, CHANGHUA COUNTY (TW)

(21) Appl. No.: 18/146,788

(22) Filed: Dec. 27, 2022

(30) Foreign Application Priority Data
Oct. 7, 2022 (TW) 111138197

(51) Int. Cl. H01L 27/06; H01L 29/20; H01L 29/778; H01L 29/786

(52) U.S. Cl. CPC H01L 27/0688; H01L 29/2003; H01L 29/7786; H01L 29/78696

(57) ABSTRACT

A group III-N based semiconductor 3D integrated circuit that directly stacks a thin-film transistor on a group III-N based transistor is provided. Since the group III-N based semiconductor 3D integrated circuit integrates the group III-N based transistor and the thin-film transistor without performing a packaging process, the group III-N based semiconductor 3D integrated circuit can reduce the packaging cost and have better circuit performance and reliability.

This application claims priority of Application No. 111138197 filed in Taiwan on 7 Oct. 2022 under 35 U.S.C. § 119; the entire contents of all of which are hereby incorporated by reference.

### BACKGROUND OF THE INVENTION

### Field of the Invention

The present invention relates to a group III-N based semiconductor circuit, particularly to a group III-N based semiconductor three-dimensional (3D) integrated circuit (IC).

### Description of the Related Art

Group III-N semiconductor circuits have been widely applied to optoelectronic devices, communication devices and high-power electronic devices. Take gallium nitride (GaN) as an example. Compared with traditional silicon (Si) materials, GaN has the advantages of wider energy gap, higher saturation current and breakdown electric field. However, due to differences in materials, GaN and Si devices cannot be fabricated on the same wafer. Thus, the GaN device is considered a discrete component. When the GaN device needs to be integrated with the Si devices, the GaN devices and the Si devices will be fabricated in different wafer. Then, the GaN device is electrically connected to the Si device by wire bonding, and the GaN device and the Si device will be finally packaged. The packaging process will cause additional costs, and the wire bonding during the packaging process will also have problems such as parasitic capacitance, parasitic inductance, and parasitic resistance, resulting in limited circuit performance and reduced reliability. In addition, to realize the enhancement-mode characteristics, GaN devices with a p-GaN gate are widely used, which is complex in the epitaxy.

The specific description and solution of the problems caused by the foregoing packaging process can refer to the following references:
[1] M.-J. Yu, R.-P. Lin, Y.-H. Chang, and T.-H. Hou, “High-Voltage Amorphous lnGaZnO TFT With Al₂O₃High-e Dielectric for Low-Temperature Monolithic 3-D Integration,” IEEE Transactions on Electron Devices, vol. 63, no. 10, pp. 3944-3949, 2016;
[2] Jeong, S. G., Jeong, H. I., & Park, J. S., “Low Subthreshold Swing and High Performance of Ultrathin PEALD InGaZnO Thin-Thin-film transistors,” IEEE Transactions on Electron Devices, 68(4), 1670-1675, 2021;
[3] BILL SCHWEBER, “48V Applications Drive Power IC Package Options,” SEMICONDUCTOR ENGINEERING: DEEP INSIGHTS FOR THE TECH INDUSTRY, Jan. 21, 2021;
[4] Huang, X., Li, Q., Liu, Z., & Lee, F. C., “Analytical loss model of high voltage GaN HEMT in cascode configuration,” IEEE Transactions on Power Electronics, 29(5), 2208-2219, 2013;
[5] Then, H. W., Radosavljevic, M., Desai, N., Ehlert, R., Hadagali, V., Jun, K., . . . & Fischer, P., “Advances in Research on 300 mm Gallium Nitride-on-Si (III) NMOS Transistor and Silicon CMOS Integration,” IEEE International Electron Devices Meeting (IEDM), pp. 27-3, 2020; and
[6] Chen, K. J., HAberlen, O., Lidow, A., lin Tsai, C., Ueda, T., Uemoto, Y., & Wu, Y, “GaN-on-Si power technology: Devices and applications,” IEEE Transactions on Electron Devices, 64(3), 779-795, 2017.

To overcome the abovementioned problems, the present invention provides a three-dimensional (3D) integrated circuit that directly stacks devices on group III-N based semiconductors.

### SUMMARY OF THE INVENTION

One objective of the present invention is to provide a group III-N based semiconductor three-dimensional (3D) integrated circuit (IC) integrated with a thin-film transistor.

According to the present invention, a group III-N based semiconductor 3D IC includes a group III-N based transistor and a thin-film transistor. The group III-N based transistor is used as a substrate. The thin-film transistor is directly stacked on the group III-N based transistor and electrically connected to the group III-N based transistor.

Since the group III-N based semiconductor 3D IC integrates the group III-N based transistor and the thin thin-film transistor without performing a packaging process, the group III-N based semiconductor 3D integrated circuit can reduce the packaging cost and have better circuit performance and reliability.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating a group III-N based semiconductor three-dimensional (3D) integrated circuit (IC) according to a first embodiment of the present invention:

FIG. 2 is a schematic diagram illustrating the equivalent circuit group of the III-N based semiconductor 3D IC of FIG. 1;

FIG. 3 is a schematic diagram illustrating a group III-N based semiconductor 3D IC according to a second embodiment of the present invention;

FIG. 4 is a schematic diagram illustrating the equivalent circuit group of the III-N based semiconductor 3D IC of FIG. 3;

FIG. 5 is a schematic diagram illustrating a group III-N based semiconductor 3D IC according to a third embodiment of the present invention; and

FIG. 6 is a schematic diagram illustrating the equivalent circuit group of the III-N based semiconductor 3D IC of FIG. 5.

### DETAILED DESCRIPTION OF THE INVENTION

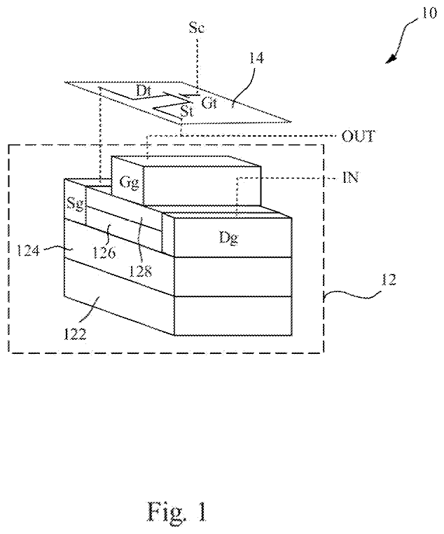

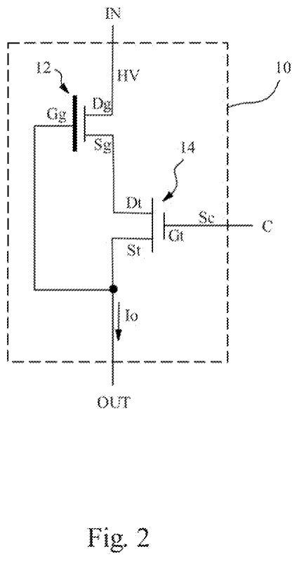

FIG. 1 is a schematic diagram illustrating a group III-N based semiconductor three-dimensional (3D) integrated circuit (IC) according to a first embodiment of the present invention. The group III-N based semiconductor 3D IC in FIG. 1 is a high-power circuit. FIG. 2 is a schematic diagram illustrating the equivalent circuit of the group III-N based semiconductor 3D IC of FIG. 1. The group III-N based semiconductor 3D IC 10 of FIG. 1 includes a high-voltage GaN metal-insulator-semiconductor high electron mobility transistor (MISHEMT) 12 and a low-voltage thin-film transistor (TFT) 14. As illustrated in FIG. 1, the GaN MISHEMT 12 includes a Si layer 122, a GaN layer 124, an AlGaN layer 126, a gate oxide layer 128, a gate Gg, a drain Dg, and a source Sg. The structure of the ITT 14 is the prior art. In FIG. 1, circuit symbols simply represent the gate Gt, the drain Dt, and the source St of the TFT 14. In the embodiment of FIG. 1, the GaN MISHEMT 12 can be replaced with another group III-N based transistor. In the group III-N based semiconductor 3D IC 10, the GaN MISHEMT 12 is used as a substrate. The TFT 14 is directly stacked on and electrically connected to the GaN MISHEMT 12, thereby forming an enhancement-mode cascade circuit.

Referring to FIG. 1 and FIG. 2, the group III-N based semiconductor 3D IC 10 has an input IN, an output OUT, and a control terminal C. The drain Dg of the GaN MISHEMT 12 is connected to the input IN. The drain Dt of the TFT 14 is connected to the source Sg of the GaN MISHEMT 12. The source St of the TFT 14 is connected to the output OUT and the gate Gg of the GaN MISHEMT 12. The gate Gt of the TFT 14 is connected to the control terminal C. The input IN is configured to receive a high voltage HV. The output OUT is configured to output a current Io. The control terminal C is connected to a control signal generator (not illustrated) and configured to receive a control signal Sc. In the embodiment of FIG. 1 and FIG. 2, the GaN MISHEMT 12 is a normally-on transistor. As a result, when the control signal Sc turns on the TFT 14, the input IN is connected to the output OUT. Thus, the output OUT will output the current Io to a circuit that is connected to the output OUT. On the contrary, when the control signal Sc turns off the TFT 14, the input IN is disconnected from the output OUT. Thus, the output OUT will stop outputting the current Io.

In an embodiment, if the control signal generator can be integrated into the group III-N based semiconductor 3D IC 10, the control terminal C can be omitted.

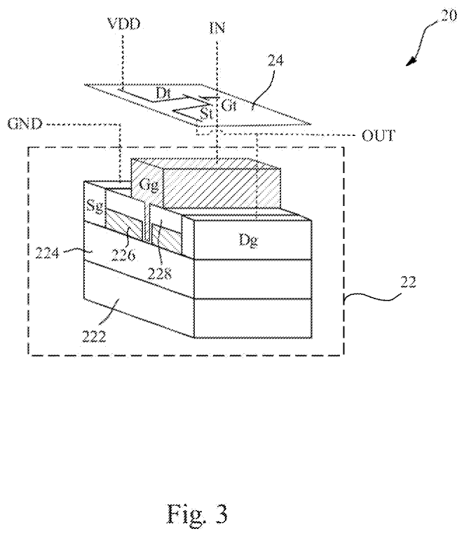

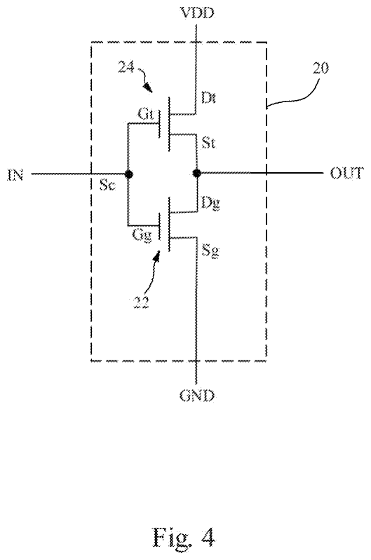

FIG. 3 is a schematic diagram illustrating a group III-N based semiconductor 3D IC according to a second embodiment of the present invention. The group III-N based semiconductor 3D IC in FIG. 3 is a CMOS inverter. FIG. 4 is a schematic diagram illustrating the equivalent circuit of the group III-N based semiconductor 3D IC of FIG. 3. A group III-N based semiconductor 3D IC 20 of FIG. 3 includes an enhancement-mode GaN transistor 22 and a P-type thin-film transistor (TFT) 24. As illustrated in FIG. 3, the enhancement-mode GaN transistor 22 is a gate-recessed metal-insulator-semiconductor high electron mobility transistor. The enhancement-mode GaN transistor 22 of FIG. 3 includes a Si layer 222, a GaN layer 224, an AlGaN layer 226, a gate oxide layer 228, a gate Gg, a drain Dg, and a source Sg. The structure of the TFT 24 is the prior art. In FIG. 3, circuit symbols simply represent the gate Gt, the drain Dt, and the source St of the TFT 24. In the embodiment of FIG. 3, the GaN transistor 22 can be replaced with another group III-N based transistor. In the group III-N based semiconductor 3D IC 20, the enhancement-mode GaN transistor 22 is used as a substrate. The TFT 24 is directly stacked on and electrically connected to the enhancement-mode GaN transistor 22, thereby forming a CMOS inverter.

Referring to FIG. 3 and FIG. 4, the group III-N based semiconductor 3D IC 20 has an input IN, an output OUT, a power terminal VDD, and a grounding terminal GND. The gate Gg of the enhancement-mode GaN transistor 22 is connected to the input IN. The drain Dg of the enhancement-mode GaN transistor 22 is connected to the output OUT. The source Sg of the enhancement-mode GaN transistor 22 is connected to the grounding GND. The gate Gt of the TFT 24 is connected to the input IN. The drain Dt of the TFT 24 is connected to the power terminal VDD. The source St of the TFT 24 is connected to the output OUT. The input IN is connected to a control signal generator (not illustrated) and configured to receive a control signal Sc. The output OUT is configured to output a voltage. In the embodiment of FIG. 3 and FIG. 4, when the control signal Sc is a low-level voltage signal, the enhancement-mode GaN transistor 22 is turned off and the TFT 24 is turned on. Thus, the power terminal VDD is connected to the output OUT, such that the output OUT sends out a high-level voltage signal. On the contrary, when the control signal Sc is a high-level voltage signal, the enhancement-mode GaN transistor 22 is turned on and the TFT 24 is turned off. Thus, the output OUT is connected to the grounding terminal GND, such that the output OUT sends out a low-level voltage signal.

In an embodiment, if the control signal generator can be integrated into the group ill-N based semiconductor 3D IC 20, the input IN can be omitted.

In an embodiment, the Si layer 222 of FIG. 3 can also be replaced with another material layer, such as a SiC layer, a sapphire layer, or a GaN layer.

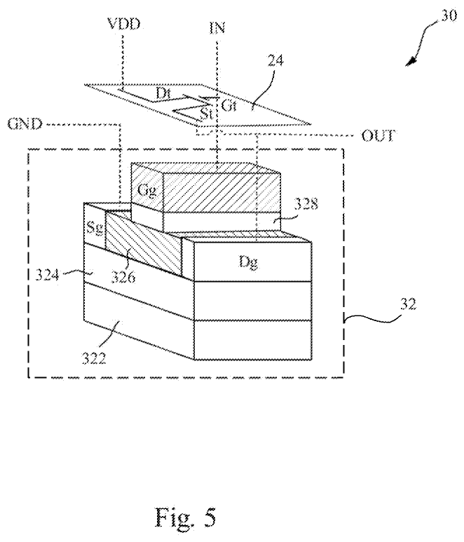

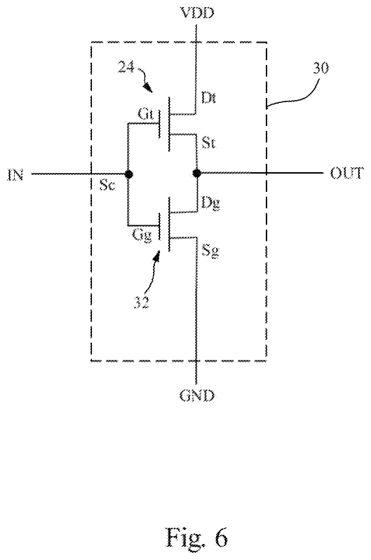

FIG. 5 is a schematic diagram illustrating a group III-N based semiconductor 3D IC according to a third embodiment of the present invention. FIG. 6 is a schematic diagram illustrating the equivalent circuit of the group III-N based semiconductor 3D 1C of FIG. 5. A group III-N based semiconductor 3D IC 30 of FIG. 5 is different from the group III-N based semiconductor 3D IC 20 of FIG. 3 in that an enhancement-mode GaN transistor 32 of the group III-N based semiconductor 3D IC 30 is a GaN high electron mobility transistor with a p-GaN gate. The enhancement-mode GaN transistor 32 of FIG. 5 includes a Si layer 322, a GaN layer 324, an AlGaN layer 326, either a P-type GaN layer or a P-type AlGaN layer 328, a gate Gg, a drain Dg, and a source Sg. The TFT 24 is directly stacked on the enhancement-mode GaN transistor 32 to from a CMOS inverter. As illustrated in FIG. 5 and FIG. 6, the gate Gg of the enhancement-mode GaN transistor 32 is connected to the input IN. The drain Dg of the enhancement-mode GaN transistor 32 is connected to the output OUT. The source Sg of the enhancement-mode GaN transistor 32 is connected to the grounding terminal GND. The gate Gt of the TFT 24 is connected to the input IN. The drain Dt of the TFT 24 is connected to the power terminal VDD. The source St of the TFT 24 is connected to the output OUT. The input IN is connected to a control signal generator (not illustrated) and configured to receive a control signal Sc. The output OUT is configured to output a voltage. When the control signal Sc is a low-level voltage signal, the enhancement-mode GaN transistor 32 is turned off and the TFT 24 is turned on. Thus, the power terminal VDD is connected to the output OUT, such that the output OUT sends out a high-level voltage signal. On the contrary, when the control signal Sc is a high-level voltage signal, the enhancement-mode GaN transistor 32 is turned on and the TFT 24 is turned off. Thus, the output OUT is connected to the grounding terminal GND, such that the output OUT sends out a low-level voltage signal.

In an embodiment, the Si layer 322 of FIG. 5 can also be replaced with a SiC layer, a sapphire layer, or a GaN layer.

FIG. 3 and FIG. 5 respectively exemplify the enhancement-mode GaN transistors with the gate-recessed metal-insulator-semiconductor high electron mobility transistor and the GaN high electron mobility transistor with a p-GaN gate, but the present invention is not limited thereto.

According to the embodiments provided in FIGS. 1-5, the present invention directly stacks the TFT on the group III-N based transistor to form a single 3D IC without performing a packaging process. Thus, the present invention does not have problems with parasitic capacitance, parasitic inductance, or parasitic resistance caused by wire bonding. In other words, the group III-N based semiconductor 3D integrated circuit of the present invention can reduce the packaging cost and have better circuit performance and reliability.

The foregoing embodiments only exemplify the enhancement-mode cascade circuit and the CMOS inverter. The group III-N based semiconductor 3D integrated circuit of the present invention is not limited to the enhancement-mode cascade circuit and the CMOS inverter.

In an embodiment, the TFT is stacked on the group III-N based transistor by a method that includes, but is not limited to, a deposition method.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A group III-N based semiconductor three-dimensional (3D) integrated circuit comprising:
a group III-N based transistor; and
a thin-film transistor, stacked on the group III-N based transistor and electrically connected to the group III-N based transistor.

2. The group III-N based semiconductor 3D integrated circuit according to claim 1, further comprising an input and an output, wherein a drain of the group III-N based transistor is connected to the input, a drain of the thin-film transistor is connected to a source of the group III-N based transistor, a source of the thin-film transistor is connected to a gate of the group III-N based transistor and the output, a gate of the thin-film transistor is configured to receive a control signal, and the control signal is configured to turn on or turn off the thin-film transistor.

3. The group III-N based semiconductor 3D integrated circuit according to claim 2, wherein the group III-N based transistor comprises a GaN metal-insulator-semiconductor high electron mobility transistor.

4. The group III-N based semiconductor 3D integrated circuit according to claim 2, wherein the thin-film transistor is an N-channel transistor.

5. The group III-N based semiconductor 3D integrated circuit according to claim 1, further comprising an input, an output, a power terminal, and a grounding terminal, wherein a drain of the group III-N based transistor is connected to the input, a drain of the group III-N based transistor is connected to the output, a source of the group III-N based transistor is connected to the grounding terminal, a gate of the thin-film transistor is connected to the input, a drain of the thin-film transistor is connected to the power terminal, a source of the thin-film transistor is connected to the output, and the group III-N based transistor and the thin-film transistor are turned on or turned off according to a control signal on the input.

6. The group III-N based semiconductor 3D integrated circuit according to claim 5, wherein the group III-N based transistor comprises an enhancement-mode GaN transistor.

7. The group III-N based semiconductor 3D integrated circuit according to claim 6, wherein the enhancement-mode GaN transistor comprises a gate-recessed high electron mobility transistor, a GaN high electron mobility transistor with a p-GaN gate, or a GaN high electron mobility transistor with a p-AlGaN gate.

8. The group III-N based semiconductor 3D integrated circuit according to claim 5, wherein the thin-film transistor is a P-channel transistor.
